(19) United States
(12) Patent Application Publication
(10) Pub. No.: US 2014/0049928 A1
(43) Pub. Date: Feb. 20, 2014

(54) SUBSTRATE WITH BUILT-IN ELECTRONIC COMPONENT

(71) Applicants: Tatsuro Sawatari, Tokyo (JP); Eiji Mugiya, Tokyo (JP); Hiroshi Nakamura, Tokyo (JP)

(72) Inventors: Tatsuro Sawatari, Tokyo (JP); Eiji Mugiya, Tokyo (JP); Hiroshi Nakamura, Tokyo (JP)

(73) Assignee: TAIYO YUDEN CO., LTD., Tokyo (JP)

(21) Appl. No.: 13/593,131

(22) Filed: Aug. 23, 2012

(30) Foreign Application Priority Data
Aug. 17, 2012 (JP) 2012-180823

(51) Int. Cl. H05K 1/18

(52) U.S. Cl. 361/762; 361/761

(57) ABSTRACT

Provided is a substrate with a built-in electronic component that can avoid as much as possible the occurrence of malfunctions in the electronic component due to moisture entering, even when an electronic component, provided with a structure in which a terminal pad is present where a hole in the sealing part provided on the main body of a component is located, is built into the substrate. A SAW filter 12 built into a substrate 11 is provided with a structure that has terminal pads 12c to 12e on the bottom of respective holes 12f1 in a sealing part 12f. The lower surfaces of respective conductive vias 11d2 are connected to the upper surfaces of the terminal pads 12c to 12e through the respective holes 12f1 such that a ring-shaped gap CC is formed between outer surfaces of the conductive vias 11d2 and inner surfaces of the holes 12f1. Each ring-shaped gap CC is filled with a part that is integral with a first insulating layer 11c.

This application claims the benefit of Japanese Application No. 2012-180823, filed in Japan on Aug. 17, 2012, which is hereby incorporated by reference in its entirety.

### TECHNICAL FIELD

The present invention relates to a substrate with a built-in electronic component in which an electronic component is built into a substrate, and particularly to a substrate with a built-in electronic component in which the electronic component, provided with a structure in which a terminal pad is present where a hole in a sealing part provided on a main body of the component is located, is built into a substrate.

### BACKGROUND ART

Patent Documents 1 and 2 below disclose an electronic component provided with a structure in which a terminal pad is present where a hole in a sealing part provided on a main body of a component is located. The electronic component disclosed in Patent Documents 1 and 2 is a SAW filter that uses a surface acoustic wave. In the SAW filter, a hollow cover that covers a part that functions as a filter is covered by a moisture resistant sealing part, and an element that corresponds to a terminal pad is located at the bottom of a hole provided in the sealing part (refer to paragraph [0083] and FIG. 13 of Patent Document 1, and paragraphs [0023] and [0049] and FIG. 1 of Patent Document 2). A SAW filter disclosed in Patent Document 3 does not have such a structure but Patent Document 3 discloses a liquid crystal polymer and syndiotactic polystyrene to be used for a moisture resistant plastic (refer to paragraph [0030]).

While the SAW filter was generally installed on the upper surface of the substrate due to the large size of the SAW filter (refer to Patent Document 3), in recent times, attempts are being made to build the SAW filter into the substrate in a similar manner to miniature electronic components such as capacitors, inductors, and resistors, as a result of miniaturization of the SAW filter due to advances in wafer-level packaging techniques.

However, when using a configuration in which a SAW filter, which is provided with a structure in which a terminal pad is present where the hole in a sealing part provided on the main body of the component is located, is built into a substrate, and a conductive via, which is provided on an insulating layer that covers the sealing part, is connected to the terminal pad of the SAW filter, there is a risk of the following problems occurring.

A moisture resistant plastic such as a liquid crystal polymer or a syndiotactic polystyrene disclosed in Patent Document 3, for example, is generally used for a sealing part that needs to be moisture resistant. However, a liquid crystal polymer and syndiotactic polystyrene, which belong to the category of thermoplastics, are less adhesive than thermosetting plastic. Thus, the vicinity of the holes in the sealing part is susceptible to a decrease in adhesion as a result of thermal expansion and contraction of the substrate with a built-in electronic component or an external force or the like such as vibration or pressure applied to the substrate with a built-in electronic component. If moisture enters past the sealed part as a result of the decrease in adhesion, this will result in a further decrease in adhesion, which results in even more moisture entering. This moisture risks causing a short circuit in the terminal pad, thus presenting a risk that the SAW filter will malfunction.

Such risk is present not only when the SAW filter is built into the substrate, but also when other types of elastic wave filters, IC chips, or the aforementioned miniature electronic components, which are provided with a structure in which a terminal pad is present where a hole in a sealing part provided on the main body of the component is located, are built into the substrate.

### RELATED ART DOCUMENT

### Patent Document

Patent Document 1: Japanese Patent Publication No. 4229122
Patent Document 2: Japanese Patent Publication No. 4670872
Patent Document 3: Japanese Patent Application Laid-Open Publication No. 2006-211612

### SUMMARY OF THE INVENTION

### Problems to be Solved by the Invention

An object of the present invention is to provide a substrate with a built-in electronic component that can avoid the occurrence of malfunctions in the electronic component resulting from moisture as much as possible, even when an electronic component, provided with a structure in which a terminal pad is present where a hole in the sealing part provided on the main body of a component is located, is built into the substrate.

### Means for Solving the Problems

In order to accomplish this object, a substrate with a built-in electronic component of the present invention includes: an electronic component built therein, the electronic component having a structure in which a terminal pad is present where a hole in a sealing part provided on a main body of the electronic component is located; a conductive via provided in an insulating layer that covers the sealing part, the conductive via being connected to the terminal pad; and a reinforcing member that is in contact with an inner surface of the hole in the sealing part, a periphery of an opening of the hole in the sealing part, and at least a part of the terminal pad.

### Effects of the Invention

The present invention has a reinforcing member that is in contact with at least a part of the inner surface of the hole in the sealing part, the periphery of the opening of the hole in the sealing part, and the terminal pad. Thus, the reinforcing member prevents moisture from entering as a result of decreased adhesion, by mitigating the decrease in adhesion in the vicinity of the hole in the sealing part. Therefore, the present invention can avoid as much as possible the occurrence of malfunctions in the electronic component resulting from moisture entering.

The aforementioned object, other objects, features, and effects of the present invention will become apparent from descriptions and appended drawings that follow.

### BRIEF DESCRIPTION OF THE DRAWINGS

FIG. 1A is a vertical cross-sectional view that shows main parts of the substrate with a built-in electronic component according to Embodiment 1 of the present invention; FIG. 1B is a partial magnified view of FIG. 1A.

FIG. 2A is a top view of an SAW filter shown in FIG. 1A, and FIG. 2B is a drawing that shows a configuration of the part of the SAW filter, shown in FIG. 2A, that functions as a filter.

FIGS. 3A to 3F are drawings that show steps for making the connective structure between the terminal pad of the SAW filter and the conductive via on the substrate side, which are shown in FIG. 1B.

FIG. 4 is a drawing according to Embodiment 2 of the present invention that corresponds to FIG. 1A.

FIG. 5A is a vertical cross-sectional view that shows main parts of a substrate with a built-in electronic component according to Embodiment 3 of the present invention, and FIG. 5B is a partial magnified view of FIG. 5A.

FIG. 6A is a top view of a SAW filter shown in FIG. 5A, and FIG. 6B is a drawing that shows a configuration of the part of the SAW filter, shown in FIG. 6A, that functions as a filter.

FIGS. 7A to 7F are drawings that show steps for making the connective structure between the terminal pad of the SAW filter and the conductive via on the substrate side, which are shown in FIG. 5B.

FIG. 8 is a drawing according to Embodiment 4 of the present invention that corresponds to FIG. 5B.

FIG. 9 is a drawing according to Embodiment 5 of the present invention that corresponds to FIG. 5A.

### DETAILED DESCRIPTION OF EMBODIMENTS

### Embodiment 1

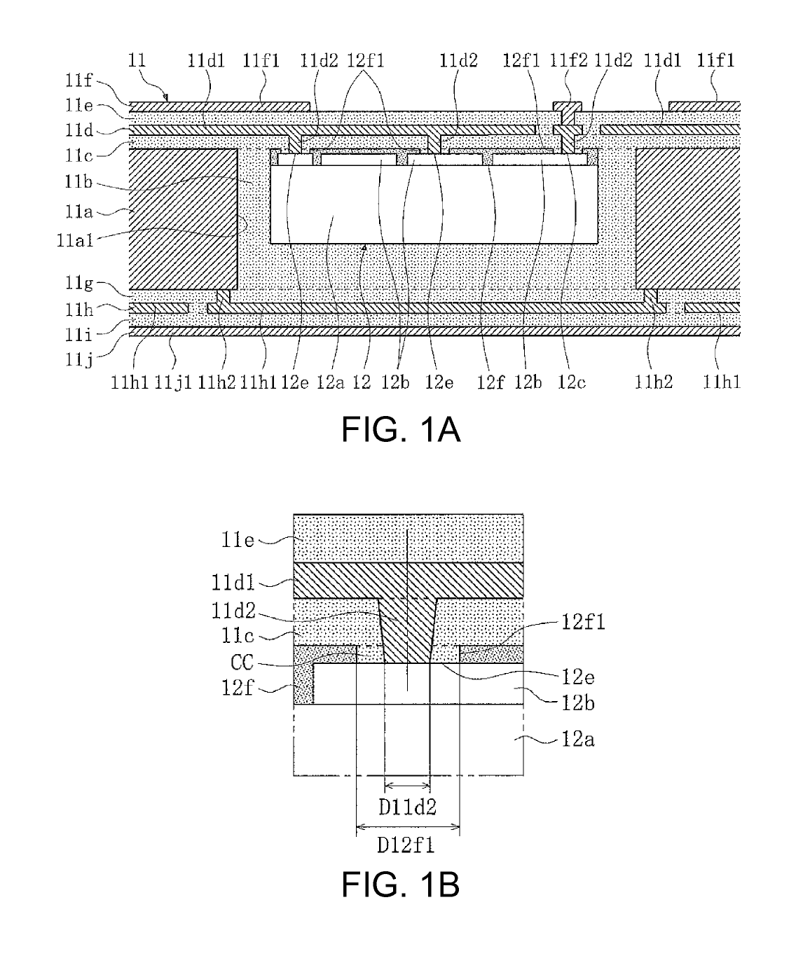

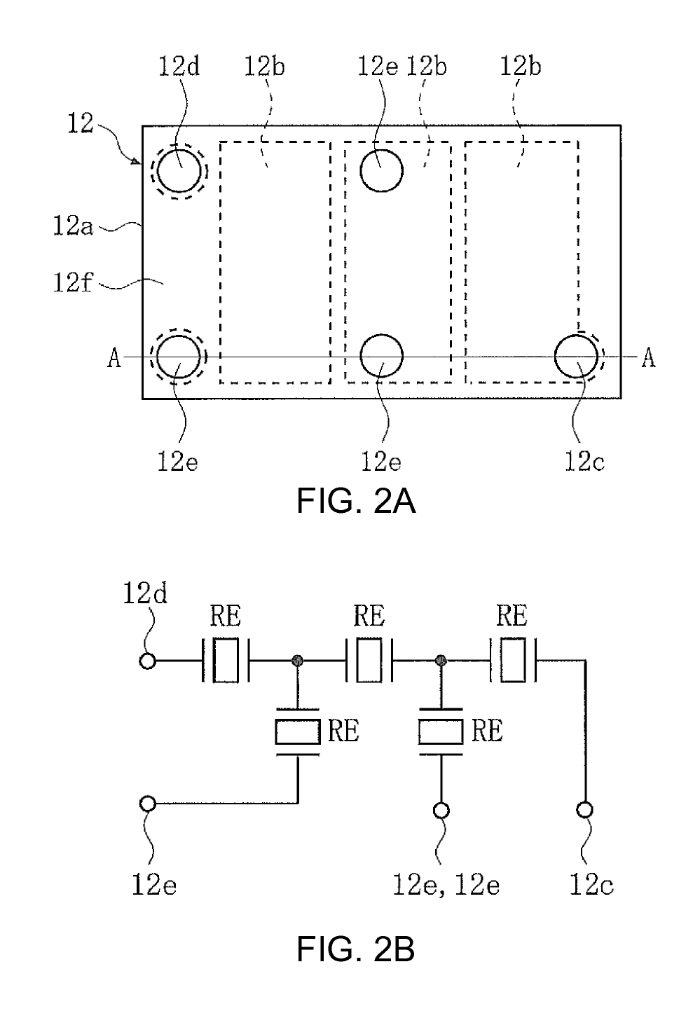

FIGS. 1A, 1B, 2A, 2B, and 3A to 3F show Embodiment 1 of the present invention (substrate with a built-in electronic component), and reference character 11 in the drawings is a multilayer substrate while reference character 12 is an SAW filter built into the substrate 11. FIG. 1A shows a cross-section along the line A-A of FIG. 2A, but FIG. 1A does not show a cross-section of the SAW filter 12, except for a sealing part 12f described below.

As shown in FIG. 1A, the substrate 11 is provided with: a core layer 11a through which a substantially rectangular cuboid-shaped storage part 11a1 is formed; a component securing part 11b provided in the gap between the SAW filter 12 stored inside the storage part 11a1 and an inner wall of the storage part 11a1; a first insulating layer 11c provided on an upper surface (first main surface) of the core layer 11a; a first conductive layer 11d provided on an upper surface of the first insulating layer 11c; a second insulating layer 11e provided on an upper surface of the first conductive layer 11d; a second conductive layer 11f provided on an upper surface of the second insulating layer 11e; a third insulating layer 11g provided on a lower surface (second main surface) of the core layer 11a; a third conductive layer 11h provided on a lower surface of the third insulating layer 11g; a fourth insulating layer 11i provided on a lower surface of the third conductive layer 11h; and a fourth conductive layer 11j provided on a lower surface of the fourth insulating layer 11i.

The core layer 11a is made of a metal such as copper or a copper alloy, and the thickness thereof is 100 μm to 400 μm, for example. The component securing part 11b is made of a thermosetting plastic such as an epoxy resin, a polyamide, a bismaleimide-triazine resin, or a resin that includes a reinforcing filler with these resins. The insulating layers 11c, 11e, 11g, and 11i are made of a thermosetting plastic such as an epoxy resin, a polyamide, a bismaleimide-triazine resin, or a resin that includes a reinforcing filler in these resins, and the thickness thereof is 10 μm to 30 μm, for example. Each conductive layer 11d, 11f, 11h, and 11j is made of a metal such as copper or a copper alloy, and the thickness thereof is 5 μm to 25 μm, for example.

Wiring lines 11d, 11f1, 11h1, and 11j1, which are used as signal wiring lines or ground wiring lines, are patterned in two dimensions in the respective conductive layers 11d, 11f, 11h, and 11j.

Each insulating layer 11c, 11e, 11g, and 11i is provided with conductive vias 11d2, 11f2, and 11h2, which are continuous or not continuous with the wiring lines 11d1, 11f1, 11h1, and 11j1 (the conductive via of the wiring line 11j1 is not shown in the drawings). Each conductive via 11d2, 11f2, and 11h2 is made of a metal such as copper or a copper alloy, and the maximum diameter thereof is 10 μm to 80 μm, for example.

A thermosetting plastic such as an epoxy resin, a polyamide, a bismaleimide-triazine resin, or a resin that includes a reinforcing filler in these resins is filled into the gaps between the respective wiring lines 11d1, 11f1, 11h1, and 11j1, and the gaps between the wiring lines 11d1, 11f1, 11h1, or 11j1 and pad parts of the non-continuous conductive vias 11d2, 11f2, or 11h2.

As shown in FIGS. 1A, 1B, and 2A, the SAW filter 12 has a filter body 12a that is substantially rectangular cuboid and made of a piezoelectric body such as lithium tantalite or lithium niobate, a part that functions as a filter (no reference character) formed on the upper surface of the filter body 12a, three hollow covers 12b that cover the part that functions as a filter, an input terminal pad 12c, an output terminal pad 12d, three ground terminal pads 12e, and a sealing part 12f provided on the upper surface of the filter body 12a, and the entire SAW filter 12 is substantially rectangular cuboid.

As shown in FIG. 2B, the part that functions as a filter has a ladder configuration that is constituted of three resonators RE that are connected in series and two resonators RE that are connected to the three resonators RE in parallel, for example. Each resonator RE is constituted of a comb-shaped electrode and reflectors disposed on both sides thereof.

Each hollow cover 12b is constituted of a substantially rectangular frame-shaped sealing ring (not shown in drawings) attached to the upper surface of the filter body 12a, and a cover plate (not shown in drawings) that is attached to the sealing ring and that covers the upper surface opening thereof, and each of the covers has a height of 10 μm to 30 μm, for example. The sealing ring and the cover plate are made of a metal such as copper, nickel, gold, or an alloy thereof. In other words, in the SAW filter 12, the parts that function as a filter are covered by each of the hollow covers 12b, and the SAW filter 12 has a structure such that the parts that function as filters are disposed inside the gaps formed by the hollow covers 12b.

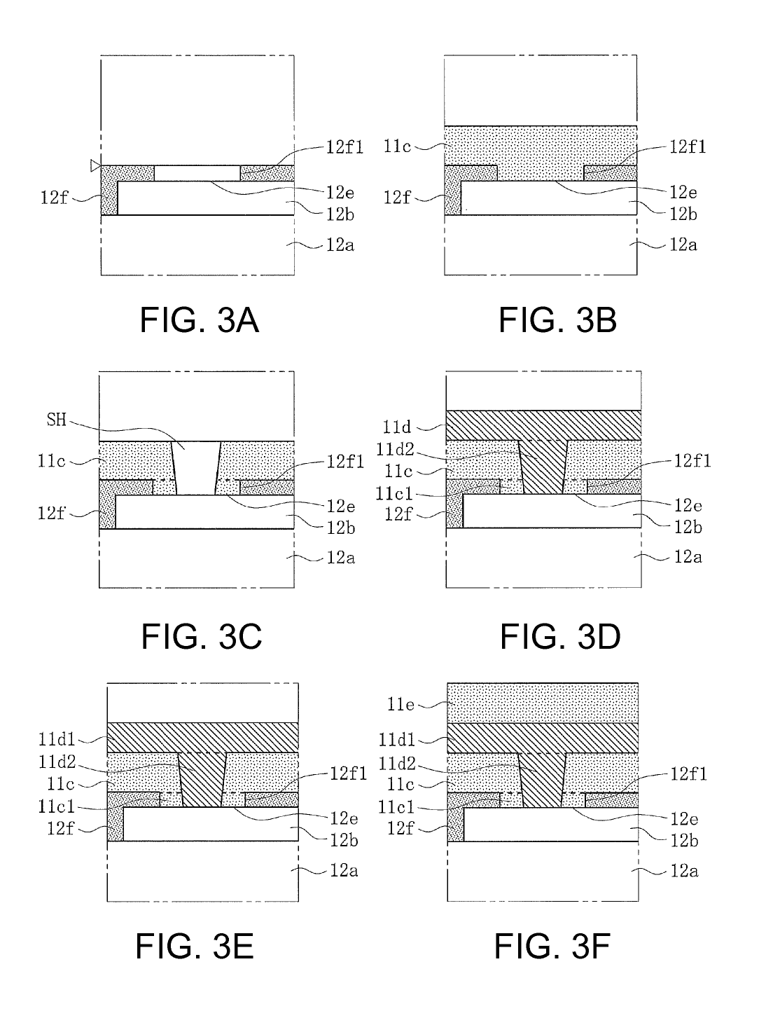

The sealing part 12f is provided on the upper surface of the filter body 12a so as to cover the hollow covers 12b. The sealing part 12f has five holes 12f1 that have a substantially circular outline formed therein, and the terminal pads 12c to 12e are disposed at the bottoms of the respective holes 12f1 (refer to FIG. 3A). The sealing part 12f is made of a thermoplastic with a high degree of moisture resistance such as a liquid crystal polymer, syndioactic polystyrene, polyphenylene sulfide, polyether ether ketone, or polyether nitrile. The thickness of the sealing part 12f on the hollow covers 12b is 10 μm to 20 μm, for example.

The SAW filter 12 is stored in the storage part 11a1 such that the terminal pads 12c to 12e face upwards, and such that the upper surface of the sealing part 12f is at approximately the same height as the upper surface of the core layer 11a. The upper surface of the sealing part 12f is covered by the first insulating layer 11c. The input terminal pad 12c of the SAW filter 12 is connected to the conductive via 11f2, which is exposed at the upper surface of the substrate 11, through the conductive via 11d2. Although not shown in drawings, the output terminal pad 12d is also connected to the conductive via 11f2, which is exposed at the upper surface of the substrate 11, through the conductive via 11d2. In addition, the ground terminal pads 12e of the SAW filter 12 are connected to the wiring lines 11d1 for grounding, through the conductive vias 11d2.

The connective structure between the conductive vias 11d2 and the terminal pads 12c to 12e of the SAW filter 12 in the substrate with a built-in electronic component shown in FIG. 1A will be described in detail along with the manufacturing steps thereof, with reference to FIGS. 1B and 3A to 3F. The connective structure and manufacturing method of the conductive vias 11d2 to the terminal pads 12c to 12e are all the same, and therefore, the connective structure of the conductive via 11d2 and the terminal pad 12e in the upper central part of FIG. 1A will be described as an example.

As can be seen from FIG. 1B, a diameter D11d2 of the lower surface of the conductive via 11d2 is less than a diameter D12f1 of the hole 12f1 of the sealing part 12f. Also, the center line of the conductive via 11d2 and that of the hole 12f1 of the sealing part 12f are at approximately the same position. Thus, the space between the outer surface of the conductive via 11d2 and the inner surface of the hole 12f1 of the sealing part 12f forms a ring-shaped gap CC. The ring-shaped gap CC is filled with a part (filler part), which is not assigned a reference character, that is integral with the first insulating layer 11c. The filler part is in contact with the outer surface of the conductive via 11d2, the inner surface of the hole 12f1 of the sealing part 12f, and a part that is not connected to the conductive via 11d2 of the terminal pad 12e. In addition, the periphery of the opening of the hole 12f1 in the sealing part 12f is in contact with the lower surface of the first insulating layer 11c, which is continuous with the outer surface of the filler part.

In making such a connective structure, the steps below can be appropriately used. First, as shown in FIG. 3A, the SAW filter 12 is stored in the storage part 11a1 such that the upper surface of the sealing part 12f is at approximately the same height as the upper surface of the core layer 11a. In FIG. 3A, the Δ symbol refers to the position of the upper surface of the core layer 11a.

Next, although not shown in drawings, the gap between the SAW filter 12 and the inner wall of the storage part 11a1 is filled with the aforementioned thermosetting plastic, thus forming the component securing part 11b. On the lower surface of the core layer 11a, the third insulating layer 11g, which is made of the thermosetting plastic, is formed. In order to form the component securing part 11b and the third insulating layer 11g, an intermediate material of thermosetting plastic, or in other words, “an intermediate material of thermosetting plastic that can be formed by adding heat and pressure and be hardened by adding heat,” can be appropriately used.

Next, as shown in FIG. 3B, the first insulating layer 11c made of the thermosetting plastic is formed on the upper surface of the core layer 11a and the upper surface of the sealing part 12f of the SAW filter 12. Also, the same plastic as the first insulating layer 11c is filled into the hole 12f1 in the sealing part 12f of the SAW filter 12. The intermediate material of thermosetting plastic can be appropriately used in the formation of the first insulating layer 11c and the filler part.

Next, as shown in FIG. 3C, a penetrating hole SH that reaches the upper surface of the terminal pad 12e and that is formed in a substantially reverse truncated cone shape is formed in the first insulating layer 11c and the filler part through laser irradiation or the like. Next, as shown in FIG. 3D, the first conductive layer 11d that is made of the aforementioned metal is formed on the upper surface of the first insulating layer 11c through electroplating or the like. The penetrating hole SH is filled with the same metal as the first conductive layer 11d, thus forming the conductive via 11d2, which is shaped in a substantially reverse truncated cone shape.

Next, as shown in FIG. 3E, the wiring line 11d1 and the like, which are used as signal wiring lines or ground wiring lines, are patterned in two dimensions onto the first conductive layer 11d, by photolithography or the like.

Next, as shown in FIG. 3F, the second insulating layer 11e made of the thermosetting plastic is formed on the upper surface of the first conductive layer 11d. The gaps between the wiring lines 11d1 and the gaps between the wiring lines 11d1 and the pad parts of the conductive vias 11d2 are filled with the same plastic as the second insulating layer 11e. The intermediate material of thermosetting plastic can be appropriately used to form the first insulating layer 11c and the filler part.

In the substrate with a built-in electronic component, the conductive vias 11d2 are connected respectively to the upper surfaces of the terminal pads 12c to 12e through the respective holes 12f2 of the sealing part 12f such that ring-shaped gaps CC are respectively formed between the outer surfaces of the conductive vias 11d2 and the inner surfaces of the holes 12f2 of the sealing part 12f. The ring-shaped gaps CC are filled with a part that is integral with the first insulating layer 11c. The filler part is in contact continuously with the outer surface of the conductive via 11d2, the inner surface of the hole 12f1 of the sealing part 12f, and the part of the terminal pad 12e not connected to the conductive via 11d2. Also, the lower surface of the first insulating layer 11c that is continuous with the outer surface of the filler part is in contact with the periphery of the opening of the hole 12f1 of the sealing part 12f.

In other words, the filler part of the insulating layer 11c and the part of the insulating layer that is in contact with the periphery of the opening of the hole 12f1 in the sealing part 12f functions as a reinforcing member that presses the vicinity of each hole of the sealing part 12f downward. Thus, a decrease in adhesion in the vicinity of the holes of the sealing part 12f resulting from thermal expansion or contraction of the substrate with a built-in electronic component or an application of an external force or the like such as vibration or pressure thereon can be mitigated. As a result, moisture that would enter as a result of a decrease in adhesion can be prevented from entering, thus avoiding as much as possible the occurrence of short circuits between the terminal pads 12c to 12e resulting from the moisture.

Even if the sealing part 12f is made of a highly moisture resistant plastic such as a liquid crystal polymer, syndiotactic polystyrene, polyphenylene sulfide, polyether ether ketone, or polyether nitrile, or in other words even if the sealing part 12f is made of a thermoplastic with a lower degree of adhesion than a thermosetting plastic, a decrease in adhesion in the vicinity of the holes of the sealing part 12f can be reliably mitigated, and the moisture that would enter as a result of a decrease in adhesion can be reliably prevented from entering.

In addition, the first insulating layer 11c (including the filler part) that covers the sealing part 12f is formed of a thermosetting plastic such as an epoxy resin, a polyamide, a bismaleimide-triazine resin, or a resin that includes a reinforcing filler with these resins, which has a higher degree of adhesion than the aforementioned moisture-resistant plastic. Thus, the adhesion can be strengthened between the thermosetting plastic and the outer surfaces of the conductive vias 11d2 and the upper surfaces of the terminal pads 12c to 12e (excluding the part that are connected to the conductive vias 11d2), a decrease in adhesion in the vicinity of the holes of the sealing part 12f can be more reliably mitigated, and moisture that would enter as a result of a decrease in adhesion can be more reliably prevented from entering.

In addition, if the upper surfaces of the terminal pads 12c to 12e (excluding the parts that are connected to the conductive vias 11d2) are roughened in advance by a chemical or physical method, the adhesion between the thermosetting plastic and the upper surfaces of the terminal pads 12c to 12e (excluding the parts that are connected to the conductive vias 11d2) can be strengthened, thus helping prevent moisture from entering.

In FIGS. 1 and 2, the SAW filter 12 was shown to have three hollow covers 12b and five terminal pads 12c to 12e. However, even if a SAW filter that has a different number of hollow covers and terminal pads is used instead of the SAW filter 12, as long as a structure is used in which terminal pads are present where the holes in the sealing part provided on the filter body are located, then effects similar to those of the SAW filter 12 can be attained. It is apparent that, even when another type of elastic wave filter is used instead of the SAW filter 12, such as a BAW filter that uses bulk acoustic waves (BAW), or the like, as long as a structure is provided in which terminal pads are present where the holes of the sealing part provided on the filter body are located, then effects similar to those of the SAW filter 12 can be attained.

### Embodiment 2

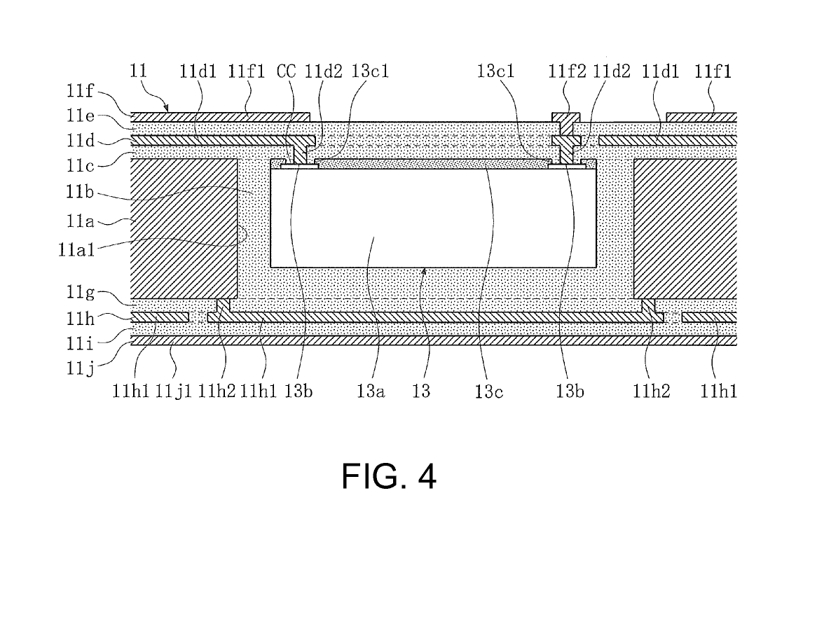

FIG. 4 shows Embodiment 2 (substrate with a built-in electronic component) of the present invention. The difference between the substrate with a built-in electronic component according to Embodiment 2 and that of Embodiment 1 is that an IC chip 13 is built into the substrate 11 instead of the SAW filter 12.

The IC chip 13 has a chip body 13a that has an integrated circuit built in, a plurality of pads 13b that are formed on an upper surface of the chip body 13a, and a sealing part 13c that is provided on the upper surface of the chip body 13a so as to cover the outer circumference part of the pads 13b. The IC chip body is substantially rectangular cuboid.

A plurality of holes 13c1 that have a substantially circular outline are formed in the sealing part 13c to correspond to the pads 13b, and terminal pads (the part excluding the outer circumference part of the pads 13b; no reference character assigned) are respectively located at the bottoms of each of the holes 13c1. The sealing part 13c is made of a thermoplastic with a high degree of moisture resistance, such as a liquid crystal polymer, syndiotactic polystyrene, polyphenylene sulfide, polyether ether ketone, and polyether nitrile. The thickness of the sealing part 13c on each pad 13b is 10 μm to 20 μm, for example.

Similar to the connective structure shown in FIG. 1B, the diameter of the lower surface of conductive vias 11d2 is less than that of each hole 13c1 of the sealing part 13c, and the center lines of the conductive vias 11d2 and the center lines of the holes 13c1 of the sealing part 13c are at approximately the same position. Thus, a ring-shaped gap CC is formed between the outer surface of each conductive via 11d2 and each hole 13c1 of the sealing part 13c. Each ring-shaped gap CC is filled with a part (no reference character) that is integral with a first insulating layer 11c. The filler parts are in contact with the outer surfaces of the conductive vias 11d2, the inner surfaces of the holes 13c1 of the sealing part 13c, and a part that is not connected to the conductive vias 11d2 of the terminal pads. In addition, lower surfaces of the first insulating layers 11c, which are continuous with the outer surfaces of the filler parts, are in contact with the periphery of the opening of each hole 1c1 of the sealing part 13c.

The substrate with a built-in electronic component according to Embodiment 2 can have effects similar to the substrate with a built-in electronic component of Embodiment 1.

FIG. 4 shows a substrate 11 with a built-in IC chip 13. However, even if another relatively large electronic component is used instead of the IC chip 13, or even if a miniature electronic component such as a capacitor, an inductor, or a resistor is used, as long as a structure is used in which terminal pads are present where the holes in the sealing part provided on the main body of a component are located, effects similar to the substrate with a built-in electronic component of Embodiment 1 can be attained.

### Embodiment 3

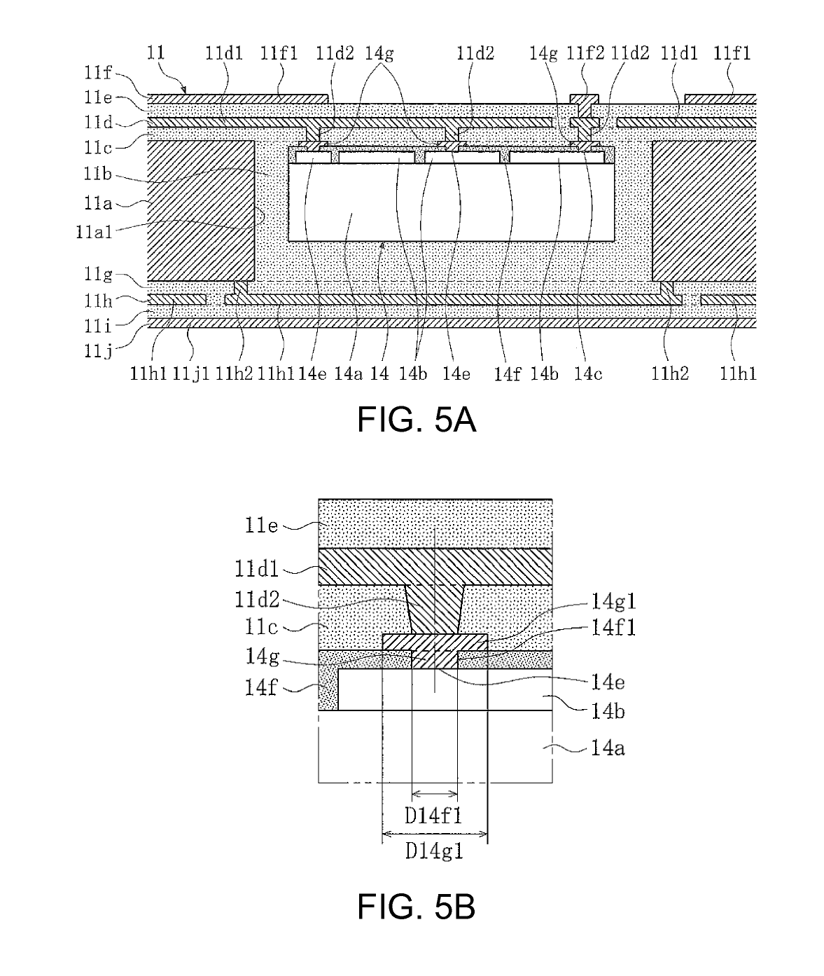

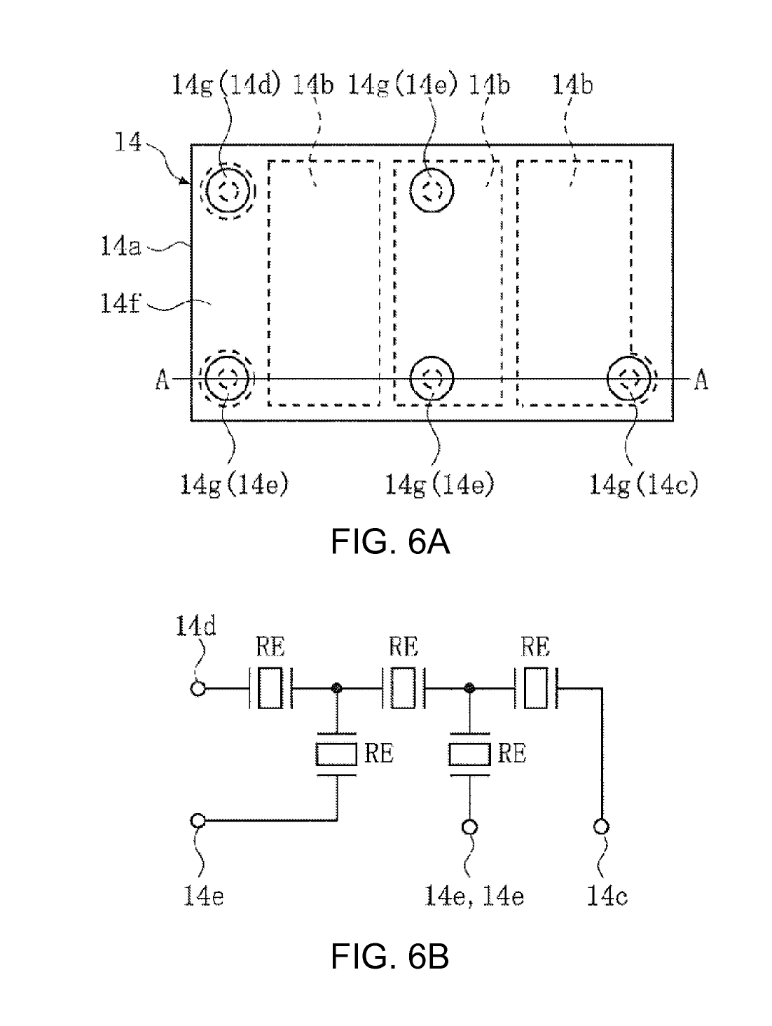

FIGS. 5A, 5B, 6A, 6B, and 7A to 7F show Embodiment 3 of the present invention (substrate with a built-in electronic component), and reference character 11 in the drawings is assigned to a multilayer substrate while reference character 14 is assigned to an SAW filter built into the substrate 11. FIG. 5A shows a cross-section along the line A-A in FIG. 6A, but FIG. 6A does not show the cross-section of the SAW filter 14, except for the sealing part 14f, which will be described below.

As shown in FIG. 5A, the substrate 11 is provided with a core layer 11a through which a substantially rectangular cuboid-shaped storage part 11a1 is formed, a component securing part 11b that is provided in the gap between the SAW filter 14 stored in the storage part 11a1 and an inner wall of the storage part 11a1, a first insulating layer 11c provided on an upper surface (first main surface) of the core layer 11a, a first conductive layer 11d provided on an upper surface of the first insulating layer 11c, a second insulating layer 11e provided on an upper surface of the first conductive layer 11d, a second conductive layer 11f provided on an upper surface of the second insulating layer 11e, a third insulating layer 11g provided on a lower surface (second main surface) of the core layer 11a, a third conductive layer 11h provided on a lower surface of the third insulating layer 11g, a fourth insulating layer 11i provided on a lower surface of the third conductive layer 11h, and a fourth conductive layer 11j provided on a lower surface of the fourth insulating layer 11i.

The core layer 11a is made of a metal such as copper or a copper alloy and the thickness thereof is 100 μm to 400 μm, for example. The component securing part 11b is made of a thermosetting plastic such as an epoxy resin, a polyamide, a bismaleimide-triazine resin, or a resin that includes a reinforcing filler with these resins. Each insulating layer 11c, 11e, 11g, and 11i is made of a thermosetting plastic such as an epoxy resin, a polyamide, a bismaleimide-triazine resin, or a resin that includes a reinforcing filler with these resins, and the thickness thereof is 10 μm to 30 μm, for example. The conductive layers 11d, 11f, 11h, and 11j are made of a metal such as copper or a copper alloy, and the thickness thereof is 5 μm to 25 μm, for example.

Wiring lines 11d1, 11f1, 11h1, and 11j1, which are used as signal wiring lines or ground wiring lines, are patterned in two dimensions in the conductive layers 11d, 11f, 11h, and 11j.

The insulating layers 11c, 11e, 11g, and 11i are provided with conductive vias 11d2, 11f2, and 11h2, which are continuous or not continuous with the wiring lines 11d1, 11f1, 11h1, and 11j1 (the conductive via of the wiring line 11j1 is not shown in drawings). The conductive vias 11d2, 11f2, and 11h2 are made of a metal such as copper or a copper alloy and the maximum diameter thereof is 10 μm to 80 μm, for example.

A thermosetting plastic such as an epoxy resin, a polyamide, a bismaleimide-triazine resin, or a resin that includes a reinforcing filler with these resins is filled into the gaps between the respective wiring lines 11d1, 11f1, 11h1, and 11j1, and the gaps between the wiring lines 11d1, 11f1, 11h1, and 11j1 and the pad parts of the non-continuous conductive vias 11d2, 11f2, and 11h2.

As shown in FIGS. 5A, 5B, and 6A, the SAW filter 14 has a substantially rectangular cuboid-shaped filter body 14a made of a piezoelectric body such as lithium tantalite or lithium niobate, a part that functions as a filter (no reference character) formed on an upper surface of the filter body 14a, three hollow covers 14b that cover the part that functions as a filter, an input relay pad 14c, an output relay pad 14d, three ground relay pads 14e, a sealing part 14f provided on an upper surface of the filter body 14a, and five terminal elements 14g provided on the respective pads for relay pads 14c to 14e. The SAW filter 14 is formed in a substantially rectangular cuboid shape as a whole.

As shown in FIG. 6B, the part that functions as a filter has a ladder configuration that is constituted of three resonators RE that are connected in series and two resonators RE connected in parallel to the three resonators RE, for example. Each resonator RE is constituted of a comb-shaped electrode and reflectors disposed on both sides thereof.

Each hollow cover 14b is constituted of a substantially rectangular frame-shaped sealing ring (not shown in drawings) connected to the upper surface of the filter body 14a, and a cover plate (not shown in drawings) that is attached to the sealing ring and that covers the openings of the upper surface thereof. The height of each cover is 10 μm to 30 μm, for example. The sealing ring and the cover plate are made of a metal such as copper, nickel, gold, or an alloy thereof. In other words, in the SAW filter 14, the parts that function as a filter are covered by hollow covers 14b, and the SAW filter 14 has a structure in which the parts that function as a filter are disposed inside the gaps formed by the hollow covers 14b.

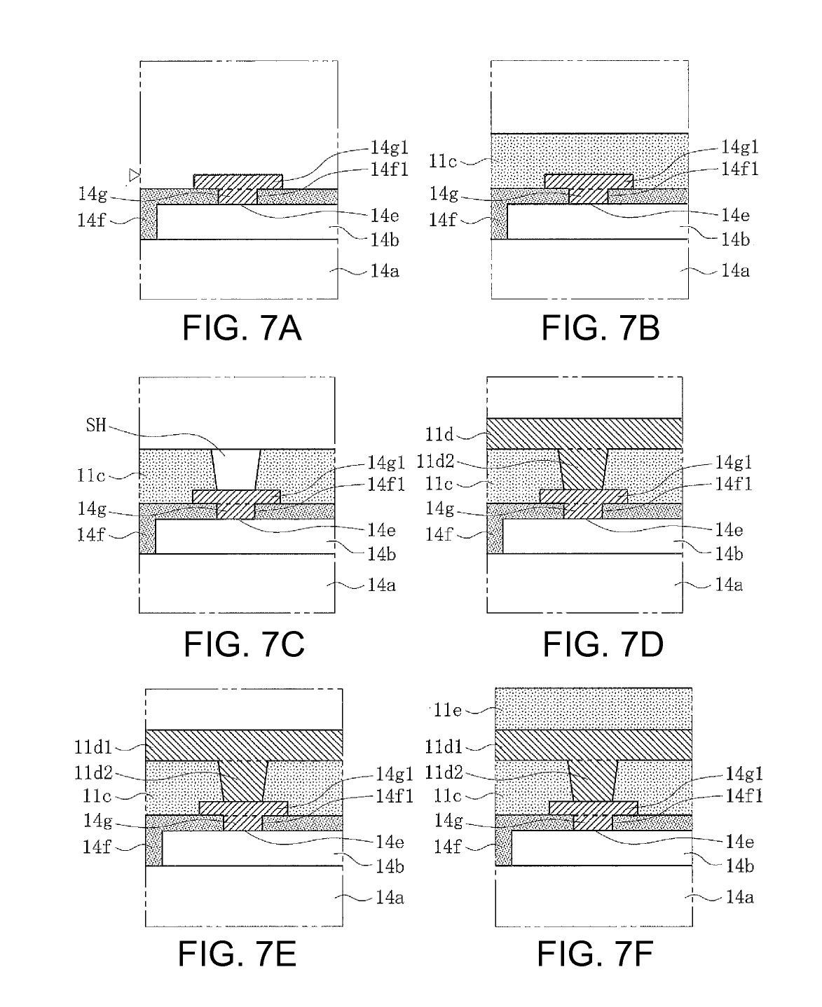

The sealing part 14f is provided on the upper surface of the filter body 14a so as to cover the hollow covers 14b. The sealing part 14f is provided with five holes 14f1 having substantially circular outlines, and relay pads 14c to 14e are respectively provided on the bottom of the respective holes 14f1 (refer to FIG. 7A). The sealing part 14f is made of a thermoplastic with a high degree of moisture resistance such as a liquid crystal polymer, syndioactic polystyrene, polyphenylene sulfide, polyether ether ketone, or polyether nitrile. The thickness of the sealing part on the hollow covers 14b is 10 μm to 20 μm, for example.

Each terminal element 14g has a substantially cylindrical columnar part (no reference character) and a substantially disk-shaped terminal pad 14g1 that is larger than the columnar part, which are integral and form a substantially T-shaped cross section. The columnar part of each terminal element 14g is in contact with the inner surface of the holes 14f of the sealing part 14f. In that state, the bottom surfaces of the terminal elements 14g are connected to the upper surfaces of the respective relay pads 14c to 14e. The lower surfaces of the terminal pads 14g1 of the terminal elements 14g are in contact with the periphery of the openings of the respective holes 14f1 of the sealing part 14f (refer to FIG. 7A). In other words, the terminal pads 14g1 are respectively located on the holes 14f1 of the sealing part 14f. The terminal elements 14g are made of a metal such as copper or a copper alloy, and the thickness of each terminal pad 14g1 is 10 μm to 20 μm, for example.

The SAW filter 14 is stored in the storage part 11a1 such that the terminal pads 14g1 face upward and such that the upper surfaces of the terminal pads 14g1 are at substantially the same height as the upper surface of the core layer 11a. The upper surface of the sealing part 14f is covered by the first insulating layer 11c. The terminal pad 14g1 that is connected to the input relay pad 14c of the SAW filter 14 is connected to the conductive via 11f2, which is exposed at the upper surface of the substrate 11, through conductive via 11d2. Although not shown in drawings, the terminal pad 14g1 connected to the output relay pad 14d is also connected to the conductive via 11f2, which is exposed at the upper surface of the substrate 11, through the conductive via 11d2. In addition, the terminal pads 14g1, which are respectively connected to the ground relay pads 14e of the SAW filter 14, are connected to the wiring lines 11d1 for grounding through conductive vias 11d2.

The connective structure of the conductive vias 11d2 and the terminal pads 14g1 of the SAW filter 14 in the substrate with a built-in electronic component shown in FIG. 5A will be described in detail below along with the manufacturing steps thereof, with reference to FIGS. 5B, and 7A to 7F. Because the connective structure and the manufacturing steps of all of the conductive vias 11d2 and the terminal pads 14g1 are the same, the connective structure between the conductive via 11d2 and the terminal pad 14g1 in the upper central part of FIG. 5A will be used as an example.

As can be seen in FIG. 5B, the columnar part of the terminal element 14g is connected to the upper surface of the relay pad 14e and in contact with the inner surface of the hole 14f1 of the sealing part 14f. Also, because the diameter D14g1 of the lower surface of the terminal pad 14g1 of the terminal element 14g is greater than the diameter D14f1 of the hole 14f1 of the sealing part 14, the lower surface of the terminal pad 14g1, which is continuous with the outer surface of the columnar part, is in contact with the periphery of the opening of the hole 14f1 in the sealing part 14f.

Furthermore, because the diameter of the lower surface of the conductive via 11d2 is less than the diameter D14g1 of the upper surface of the terminal pad 14g1 of the terminal element 14g and the center line of the conductive via 11d2 and the center line of the terminal pad 14g1 are approximately at the same position, the upper surface and the circumferential surface of the terminal pad 14g1 (excluding the part that connects to the conductive via 11d2) are in contact with the first insulating layer 11c.

In order to make such a connective structure, the steps below can be used appropriately. First, as shown in FIG. 7A, the SAW filter 14 is stored in the storage part 11a1 such that the upper surfaces of the terminal pads 14g1 are at approximately the same height as the upper surface of the core layer 11a. Also, the Δ symbol in FIG. 7A represents the position of the upper surface of the core layer 11a.

Next, the gap between the SAW filter 14 and the inner wall of the storage part 11a1 is filled with the aforementioned thermosetting plastic, forming the component securing part 11b, and the third insulating layer 11g made of the thermosetting plastic is formed on the lower surface of the core layer 11a, although this is not shown in drawings. An intermediate material of thermosetting plastic, or in other words, “an intermediate material of thermosetting plastic that can be formed by adding heat and pressure and cured by adding heat” can be appropriately used for forming the component securing part 11b and the third insulating layer 11g.

Next, as shown in FIG. 7B, the first insulating layer 11c made of the thermosetting plastic is formed on the upper surface of the core layer 11a and the upper surface of the terminal pads 14g1 of the terminal elements 14g of the SAW filter 14. The same plastic used in the first insulating layer 11c fills in the step formed by the differing heights of the upper surface of the terminal pad 14g1 and the upper surface of the sealing part 14f. The intermediate material of thermosetting plastic can be appropriately used to form the first insulating layer 11c and the filler part.

Next, as shown in FIG. 7C, a penetrating hole SH in a substantially reverse truncated cone shape, which reaches the upper surface of the terminal pad 14g1, is formed in the first insulating layer 11c through laser irradiation or the like. Next, as shown in FIG. 7D, the first conductive layer 11d made of the aforementioned metal is formed on the upper surface of the first insulating layer 11c through electroplating or the like, and a conductive via 11d2 in a substantially reverse truncated cone shape is made by filling the penetrating hole SH with the same metal used in the first conductive layer 11d.

Next, as shown in FIG. 7E, wiring lines 11d1 and the like, which are used as signal wiring lines or ground wiring lines, are patterned in two dimensions onto the first conductive layer 11d by photolithography or the like.

Next, as shown in FIG. 7F, the second insulating layer 11e made of the thermosetting plastic is formed on the first conductive layer 11d, and the gap between the wiring lines 11d1 and the gap between the wiring line 11d1 and the pad part of the conductive via 11d2 are filled with the same plastic as the second insulating layer 11e. The intermediate material of thermosetting plastic can be appropriately used for forming the first insulating layer 11c and the filler part.

In the substrate with a built-in electronic component, the columnar parts of the terminal elements 14g of the SAW filter 14 are connected to the upper surfaces of the respective relay pads 14a to 14e, and are also in contact with the inner surfaces of the respective holes 14f1 of the sealing part 14f. Also, the lower surfaces of the terminal pads 14g1, which are continuous with the outer surfaces of the respective columnar parts, are in contact with the periphery of the openings of the holes 14f1 of the sealing part 14f.

In other words, the columnar parts and the terminal pads 14g1 of the respective terminal elements 14g function as reinforcing members that press the vicinity of the holes in the sealing part 14f downward. Thus, a decrease in adhesion in the vicinity of the holes in the sealing part 14f resulting from thermal expansion or contraction of the substrate with a built-in electronic component or an external force such as vibration or pressure applied thereon can be mitigated. As a result, moisture that would enter as a result of a decrease in adhesion can be prevented from entering, thus avoiding as much as possible short circuits occurring between the terminal pads 14g1 and the relay pads 14c to 14e as a result of the moisture.

Even if the sealing part 14f is made of a highly moisture resistant plastic such as a liquid crystal polymer, syndiotactic polystyrene, polyphenylene sulfide, polyether ether ketone, or polyether nitrile, or in other words even if the sealing part 14f is made of a thermoplastic with a lower degree of adhesion than a thermosetting plastic, a decrease in adhesion in the vicinity of the holes in the sealing part 14f can be reliably mitigated, and the moisture that would enter as a result of a decrease in adhesion can be reliably prevented from entering.

In addition, the first insulating layer 11c that covers the sealing part 14f is formed of a thermosetting plastic such as an epoxy resin, a polyamide, a bismaleimide-triazine resin, or a resin that includes a reinforcing filler with those resins, which has a higher degree of adhesion than the aforementioned moisture-resistant plastic. Thus, the adhesion can be strengthened between the thermosetting plastic and the upper surfaces (excluding the part that is connected to the conductive via 11d2) and circumferential surfaces of the terminal pads 14g1, a decrease in adhesion in the vicinity of the holes of the sealing part 14f can be reliably mitigated, and moisture that would enter due to a decrease in adhesion can be reliably prevented from entering.

In addition, if the upper surfaces of the terminal pads 14g1 (excluding the parts that are connected to the conductive vias 11d2) are roughened in advance by a chemical or physical method, the adhesion between the thermosetting plastic and the upper surfaces of the terminal pads 14g1 (excluding the parts that are connected to the conductive vias 11d2) can be strengthened, thus helping prevent moisture from entering.

In FIGS. 5 and 6, the SAW filter 14 was shown to have three hollow covers 14b and five terminal pads 14g. However, even if an SAW filter that has a different number of hollow covers and terminal pads is used instead of the SAW filter 14, as long as a structure is used in which terminal pads are present where the holes in the sealing part provided on the filter body are located, then effects similar to those of the SAW filter 14 can be attained. It is apparent that, even when another type of elastic wave filter is used instead of the SAW filter 14, such as a BAW filter that uses bulk acoustic waves (BAW), as long as a structure is used in which terminal pads are present where the holes of the sealing part provided on the filter body are located, then effects similar to those of the SAW filter 14 can be attained.

### Embodiment 4

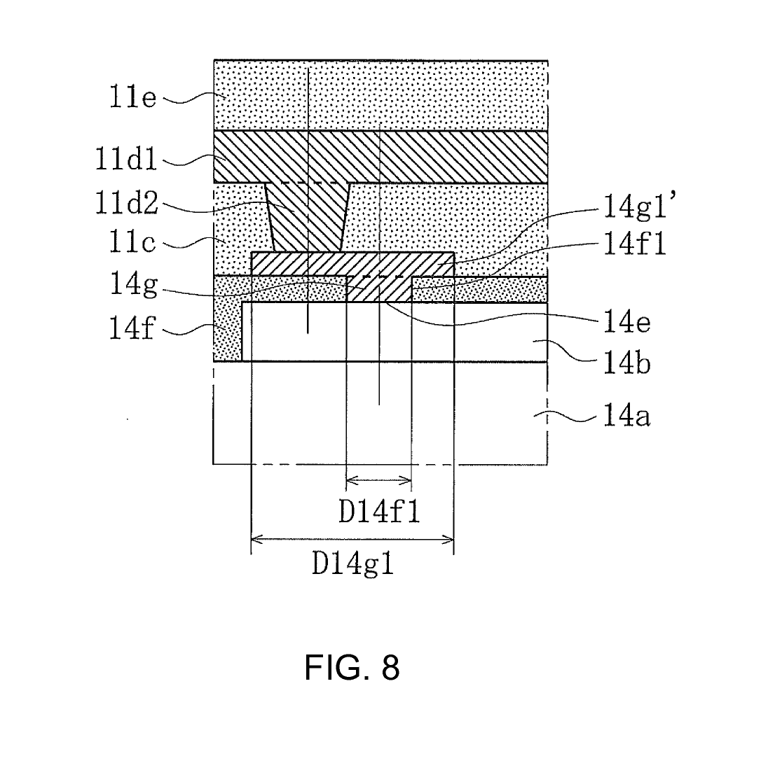

FIG. 8 shows Embodiment 4 (substrate with a built-in electronic component) of the present invention. A substrate with a built-in electronic component according to Embodiment 4 differs from the substrate with a built-in electronic component of Embodiment 3 in that outlines of terminal pads 14g1′ of terminal elements 14g of an SAW filter 14 are made larger, and the conductive vias 11d2 are arranged such that center lines thereof are offset from center lines of the columnar parts of the terminal elements 14g, and the lower surfaces of the conductive vias 11d2 are connected to the upper surfaces of the terminal pads 14g1′ of the terminal elements 14g.

It is possible to attain effects similar to the substrate with a built-in electronic component of Embodiment 3 with the substrate with a built-in electronic component according to Embodiment 4. In addition, the area where the lower surfaces of the terminal pads 14g1′ of the terminal elements 14g are in contact with the periphery of the openings of holes 14f1 of a sealing part 14f can be increased, thus exhibiting the aforementioned effects even more effectively.

In FIG. 8, similar to the substrate with a built-in electronic component of Embodiment 3, the SAW filter 14 was shown to have three hollow covers 14b and five terminal pads 14g. However, even if an SAW filter that has a different number of hollow covers and terminal pads is used instead of the SAW filter 14, as long as a structure is used in which terminal pads are present where the holes in the sealing part provided on the filter body are located, then effects similar to those of the SAW filter 14 can be attained. It is apparent that, even when another type of elastic wave filter is used instead of the SAW filter 14, such as a BAW filter, as long as a structure is used in which terminal pads are present where the holes of the sealing part provided on the filter body are located, then effects similar to those of the SAW filter 14 can be attained.

### Embodiment 5

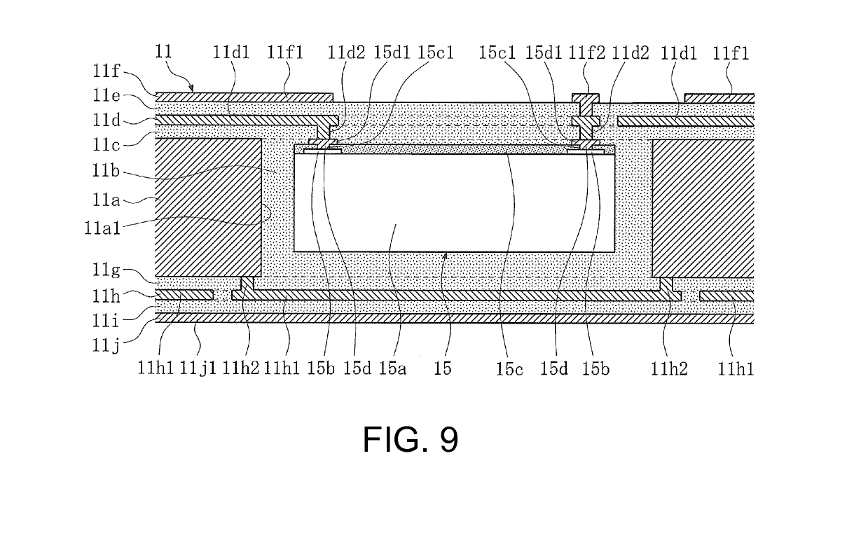

FIG. 9 shows Embodiment 5 (substrate with a built-in electronic component) of the present invention. A substrate with a built-in electronic component according to Embodiment 5 differs from the substrate with a built-in electronic component of Embodiment 3 in that an IC chip 15 is built into a substrate 11 instead of the SAW filter 14.

The IC chip 15 has a chip body 15a with an integrated circuit built in, a plurality of pads 15b formed on an upper surface of the chip body 15a, a sealing part 15c provided on the upper surface of the chip body 15a so as to cover an outer circumference part of the pads 15b, and a plurality of terminal elements 15d provided on the respective pads 15b. The IC chip 15 is substantially rectangular cuboid as a whole.

The sealing part 15c is provided with a plurality of holes 15c1 with substantially circular outlines for the respective pads 15b, and relay pads (part that excludes the outer circumference parts of the pads 15b; no reference character) are respectively located on the bottom of the respective holes 15c1. The sealing part 15c is made of a thermoplastic with a high degree of moisture resistance, such as a liquid crystal polymer, syndiotactic polystyrene, polyphenylene sulfide, polyether ether ketone, and polyether nitrile. The thickness of the sealing part 15c on each pad 15b is 10 μm to 20 μm, for example.

Each terminal element 15d has a substantially cylindrical columnar part (no reference character) and a substantially disk-shaped terminal pad 15d1 that is larger than the columnar part, which are formed so as to be integral and have a substantially T-shaped cross section. The columnar parts of each terminal element 15d is in contact with the inner surface of each hole 15c1 in the sealing part 15c. In that state, the lower surfaces of the columnar parts are in contact with the upper surfaces of the respective relay pads. The lower surfaces of the terminal pads 15d1 of the terminal elements 15d are in contact with the periphery of the openings of the respective holes 15c1 of the sealing part 15c (refer to FIG. 7A). In other words, each terminal pad 15d1 is located on the respective holes 15c1 of the sealing part 15c. The terminal elements 15d are made of a metal such as copper or a copper alloy, and the thickness of each terminal pad 15d1 is 10 μm to 20 μm, for example.

Similar to the connective structure shown in FIG. 5B, the columnar part of each terminal element 15d is connected to the upper surface of each relay pad and is in contact with the inner surface of each hole 15c1 in the sealing part 15c. Also, the lower surface of the terminal pad 15d1 of each terminal element 15d has a greater diameter than each hole 15c1 of the sealing part 15c, and therefore, the lower surface of each terminal pad 15d1, which is continuous with the outer surface of the columnar part, is in contact with the vicinity of the opening of each hole 15c1 of the sealing part 15c.

Furthermore, the lower surface of each conductive via 11d2 has a smaller diameter than the upper surface of the terminal pad 15d1 of each terminal element 15d, and the center line of each conductive via 11d2 is in approximately the same position as the center line of each terminal pad 15d1, and therefore, the upper surface (excluding the part that is connected to the conductive via 11d2) and the circumferential surface of each terminal pad 15d1 is in contact with a first insulating layer 11c.

The substrate with a built-in electronic component according to Embodiment 5 can also attain effects similar to the substrate with a built-in electronic component of Embodiment 3.

FIG. 9 shows a substrate 11 with an IC chip 15 built in. However, even if another relatively large electronic component is used instead of the IC chip 15, or even if a miniature electronic component such as a capacitor, an inductor, or a resistor is used, effects similar to the substrate with a built-in electronic component of Embodiment 3 can be attained as long as a structure is used in which terminal pads are present where the holes of the sealing part provided on the main body of a component are located.

### Other Embodiments

(1) Embodiment 1 to Embodiment 5 showed cases in which a substantially rectangular cuboid-shaped storage part 11a1 is formed through the core layer 11a of the substrate 11, but the shape of the storage part 11a1 is not limited to a substantially rectangular cuboid shape as long as a prescribed electronic component can be stored. Furthermore, it is possible to attain similar effects even when a recessed storage part is formed in the core layer 11a instead of the penetrating storage part 11a1 and an electronic component is stored in the recessed storage part.

(2) Embodiment 1 to Embodiment 5 showed cases in which two insulating layers 11c and 11e and two conductive layers 11d and 11f are provided on the upper side of the core layer 11a, and two insulating layers 11g and 11i and two conductive layers 11h and 11j are provided on the lower side thereof, for the substrate 11. However, it is possible to attain similar effects even when using a configuration in which the second insulating layer 11e and the second conductive layer 11f are omitted from the upper side of the core layer 11a, or a configuration in which additional insulating layers and conductive layers are provided on the second conductive layer on the upper side of the core layer 11a. Also, it goes without saying that the aforementioned effects can be attained even when the number of insulating layers and the number conductive layers on the lower side of the core layer 11a are appropriately increased or decreased.

(3) Embodiment 1 to Embodiment 5 showed that the core layer 11a of the substrate 11 is made of a metal. However, similar effects can be attained even when a core layer that is made of an insulator such as plastic and that has the same thickness as the core layer 11a is used instead of the core layer 11a, or a core layer that is configured by laminating insulating layers with the same thickness as the respective insulating layers 11c, 11e, 11g, and 11i is used.

### DESCRIPTION OF REFERENCE CHARACTERS

11 substrate
11a core layer
11a1 storage part
11b component securing part
11c, 11e, 11g, 11i insulating layer
11d, 11f, 11h, 11j conductive layer
11d1, 11f1, 11h1, 11j1 wiring line
11d2, 11f2, 11h2 conductive via
12 SAW filter
12a filter body
12b hollow cover
12c to 12e terminal pad
12f sealing part
12f1 hole
CC ring-shaped gap
13 IC chip
13a chip body
13b pad
13c sealing part
13c1 hole
CC ring-shaped gap
14 SAW filter
14a filter body
14b hollow cover
14c to 14e relay pad
14f sealing part
14f1 hole
14g terminal element
14g1, 14g1′ terminal pad
15 IC chip
15a chip body
15b pad
15c sealing part
15c1 hole
15d terminal element
15d1 terminal pad

1. A substrate with a built-in electronic component, comprising:
a core layer;
an electronic component built in the core layer, the electronic component having a terminal pad where a hole in a sealing part provided on at least a portion of the electronic component is located;
a conductive via provided in an insulating layer that covers the sealing part, the conductive via being connected to the terminal pad; and
a reinforcing member that is in contact with an inner surface of the hole in the sealing part, a periphery of an opening of the hole in the sealing part, and at least a part of the terminal pad.

2. The substrate with a built-in electronic component according to claim 1,
wherein the electronic component has a structure in which the terminal pad is present on a bottom of the hole in the sealing part,
wherein the conductive via is connected to the terminal pad through the hole in the sealing part such that a ring-shaped gap is formed between an outer surface of the conductive via and the inner surface of the hole in the sealing part,
wherein the insulating layer has a filler part that is integrally formed therewith, the filler part filling the ring-shaped gap and being in contact with the outer surface of the conductive via, the inner surface of the hole in the sealing part, and a part that is not connected to the conductive via of the terminal pad, and
wherein the reinforcing member is constituted of the filler part of the insulating layer and a part of the insulating layer that is in contact with the periphery of the opening of the hole in the sealing part.

3. The substrate with a built-in electronic component according to claim 1,
wherein the electronic component comprises: a relay pad on the bottom of the hole in the sealing part; and a terminal element that has a substantially T-shaped cross section, the terminal element being integrally formed of: a columnar part connected to the relay pad and in contact with the inner surface of the hole in the sealing part; and a terminal pad that is larger than the columnar part and that is in contact with the periphery of the opening of the hole in the sealing part,
wherein the conductive via is connected to the terminal pad of the terminal element, and
wherein the reinforcing member is constituted of the columnar part and the terminal pad of the terminal element.

4. The substrate with a built-in electronic component according to claim 3,
wherein the conductive via is connected to the terminal pad such that a center line of the conductive via is offset from a center line of the columnar part of the terminal element.

5. The substrate with a built-in electronic component according to claim 1,
wherein the sealing part is made of a thermoplastic, and the insulating layer is made of a thermosetting plastic.

6. The substrate with a built-in electronic component according to claim 1,
wherein the electronic component is an elastic wave filter.
